(19) United States
(12) Patent Application Publication
(10) Pub. No.: US 2011/0316145 A1
(43) Pub. Date: Dec. 29, 2011

(54) NANO/MICRO-STRUCTURE AND FABRICATION METHOD THEREOF

(75) Inventors: Chia-Wen TSAO, Taoyuan County (TW); Chia-Pin CHANG, Taoyuan County (TW); Wen-Yih CHEN, Taoyuan County (TW); Chih-Cheng CHIEN, Taipei County (TW); Yu-Che CHENG, Taipei City (TW)

(73) Assignee: NATIONAL CENTRAL UNIVERSITY, TAOYUAN COUNTY (TW)

(21) Appl. No.: 13/018,444

(22) Filed: Feb. 1, 2011

(30) Foreign Application Priority Data
Jun. 29, 2010 (TW) 99121265

(51) Int. Cl. H01L 23/48; H01L 21/28

(52) U.S. Cl. 257/734; 438/678; 257/E21.158; 257/E23.01

(57) ABSTRACT

A nano/micro-structure and a fabrication method thereof are provided. The method combines electroless plating and metal-assist etching to fabricate nano/micro-structure on a silicon substrate.

### CROSS-REFERENCE TO RELATED APPLICATION

This application claims the priority benefit of Taiwan application serial no. 99121265, filed Jun. 29, 2010, the full disclosure of which is incorporated herein by reference.

### BACKGROUND

1. Technical Field

The disclosure relates to a nano/micro-structure. More particularly, the disclosure relates to a nano/micro-structure and a preparation method thereof.

2. Description of Related Art

In the conventional nanofabrication technique using electrochemical etching, complicate surface treatment of a silicon substrate is needed. Then, the silicon substrate is immersed in a solution having complex composition and via the guiding of electrical current or light source to produce the nano/micro-structure. Moreover, the shape of the nano/micro-structure is limited to only porous. Other conventional nanofabrication techniques need expensive apparatus to perform vapor deposition, or produce electron beam or laser and are more time-consuming.

### SUMMARY

In one aspect, the present invention is directed to a nano/micro-structure and a preparation method thereof. The preparation method combines electroless plating and metal-assist etching to form nano/micro-structure on a silicon substrate.

The method comprising the following steps. A silicon substrate is immersed in an electroless plating solution to deposit a plurality of metal particles on the silicon substrate with various metal particles coverage. After washing, the silicon substrate is immersed in a metal-assist etching solution to etch the silicon substrate under the metal particles to form a plurality of nano/microstructures with various shapes.

In the forgoing, only wet processes are used in the preparation method, and the preparation method can be performed under room temperature and atmospheric pressure. Therefore, nano/micro-structures can be formed in a rapid, low energy consumption, and low cost way.

The statement above presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

Many of the attendant features will be more readily appreciated as the same becomes better understood by reference to the following detailed description considered in connection with the accompanying drawings.

### BRIEF DESCRIPTION OF THE DRAWINGS

FIG. 1 is a process flow diagram of preparing nano/micro-structure according to an embodiment of this invention.

FIGS. 2A-2C are SEM photographs of metal particles on silicon substrate of Examples 1-3, respectively.

FIGS. 3A-3C are SEM photographs of metal particles on silicon substrate of Examples 4-6, respectively.

FIGS. 4A-4C are SEM photographs showing various shapes of nano/micro-structure of examples 1-3, where the photographs on the left are top vies and photographs on the right are lateral view.

FIGS. 5A-5B are SEM photographs showing various shapes of nano/micro-structure of examples 4-5, where the photographs on the left are top vies and photographs on the right are lateral view.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### Preparation Method of Nano/Micro-Structure

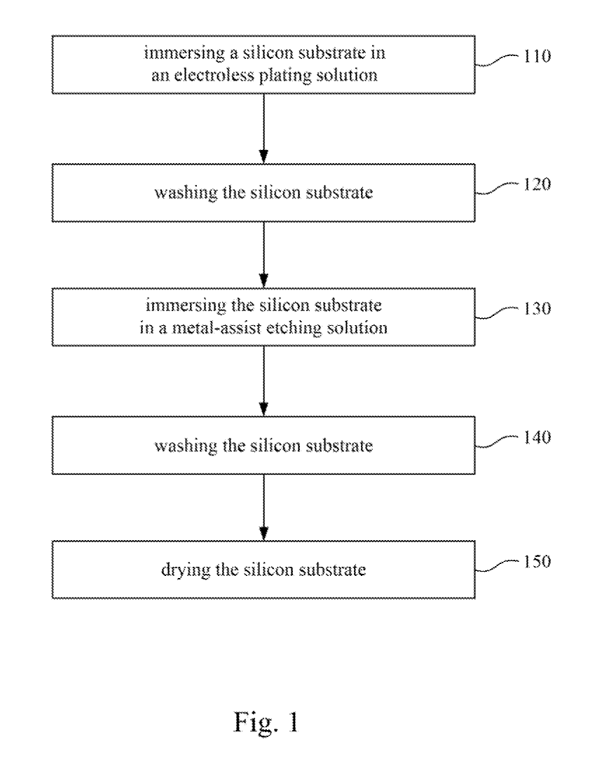

FIG. 1 is a process flow diagram of preparing nano/micro-structure according to an embodiment of this invention. In step 110 of FIG. 1, a silicon substrate is immersed in an electroless plating solution to deposit a plurality of metal particles on the silicon substrate with various metal particles coverage. The silicon substrate can be a single crystal silicon substrate, for example. The electroless plating solution comprises a metal ion and HF, and the solvent thereof is deionized water. The metal ion can be Au³⁺, Ag⁺, Pt⁴⁺ or Cu²⁺, for example, and the concentration of the metal ion is about 10⁻² M.

The HF in the electroless plating solution is mainly used to etch silicon substrate to form some mall pits and holes to create some negative charges. Therefore, metal ions can be easily absorbed by the surface of the silicon substrate and then be reduced by these negative charges to form metal particles.

The shapes of the nano/micro-structure are affected by the various metal particles coverage on the silicon substrate, which is about 5-70%. When the metal particles coverage is lower, porous nano micro-structures are obtained. When the metal particles coverage is higher, wire nano/micro-structures are obtained. When the metal particles coverage is between the two above, filament nano/micro-structures are obtained.

Generally, the metal particles coverage is controlled by concentration of metal on in the electroless plating solution and the deposition time of the metal ions. When the concentration of the metal ions is greater, the deposition rate is faster, and then the metal particles coverage is greater for the same deposition time. Contrarily, the metal particles coverage is smaller for the same deposition time. If the metal ion concentration is the same, the metal particles coverage is greater when the deposition time is longer. Contrarily, the metal particles coverage is smaller for the shorter deposition time.

Therefore, the concentration and the deposition time of the metal ions can be adjusted to control the metal particles coverage and thus the shapes of the nano/micro-structures according to the needs. According to the present experimental results, the needed metal particles coverage can be obtained in tens of seconds.

Furthermore, HF concentration can also affect the deposition rate of the metal particles. The deposition rate is higher when the HF concentration is higher.

In step 120 of FIG. 1, the silicon substrate is taken out from the electroless plating solution. The silicon substrate is then washed by deionized water for preparing the following etching step.

In step 130 of FIG. 1, the silicon substrate is immersed in a metal-assist etching solution to etch the silicon substrate under the metal particles to form nano/micro-structure with various shapes. The metal-assist etching solution comprises HF and H₂O₂, and can further comprise a solvent, such as methanol, ethanol, acetone, acetonitrile, isopropanol, or water, for example, to increase the wetting ability of the etching solution to the silicon substrate.

H₂O₂ in the metal-assist etching solution is used to perform local redox reaction at the metal particles sites to weaken or assist breaking the Si—Si bonding of the silicon substrate. Therefore, the silicon substrate can be etched more easily. The HF in the metal-assist etching solution is used for etching the silicon substrate. Since the Si—Si bonding has been weaken or broken, the HF etching is mainly anisotropic to form nano/micro-structure on the surface of the silicon substrate. Ethanol added to the metal-assist etching solution is used to be as a solvent to dissolve the various species during the etching reaction. Especially for the deeper etching, ethanol can help to diffuse the various species of the etching reaction to facilitate the etching going.

Accordingly, the ratio of lateral etching rate over vertical etching rate will be decreased when HF concentration increases. Therefore, the shape of nano/micro-structure tends to porous structure but not wire structure, under the same metal particles coverage, when the HF concentration increases.

In step 140 of FIG. 1, the silicon substrate is taken out from the metal-assist solution and then washed with deionized water. In step 150 of FIG. 1, the silicon substrate is dried.

Some working examples are stated below to further illustrate the preparation method of the nano/micro-structure.

### Embodiment 1

### Effect of Metal Deposition Time on Metal Particles Coverage

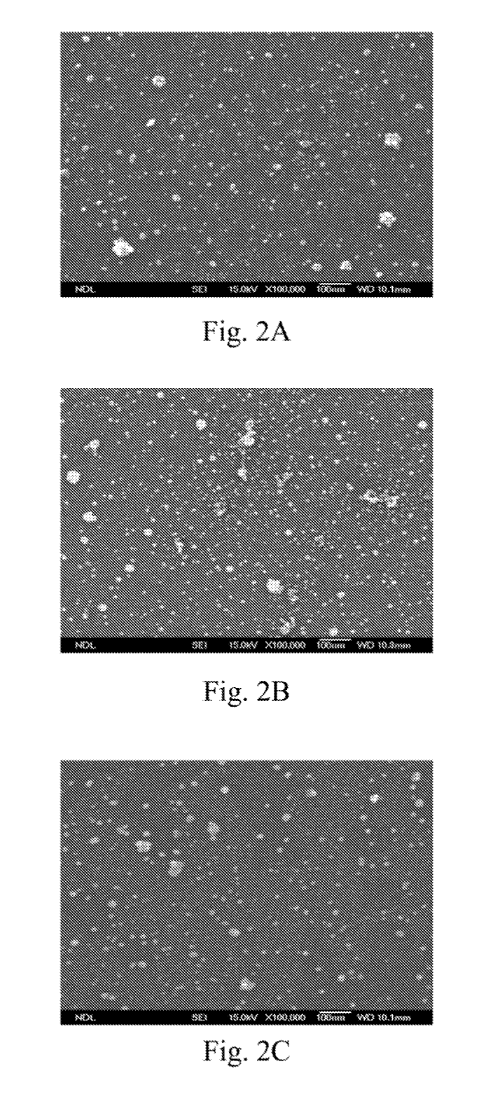

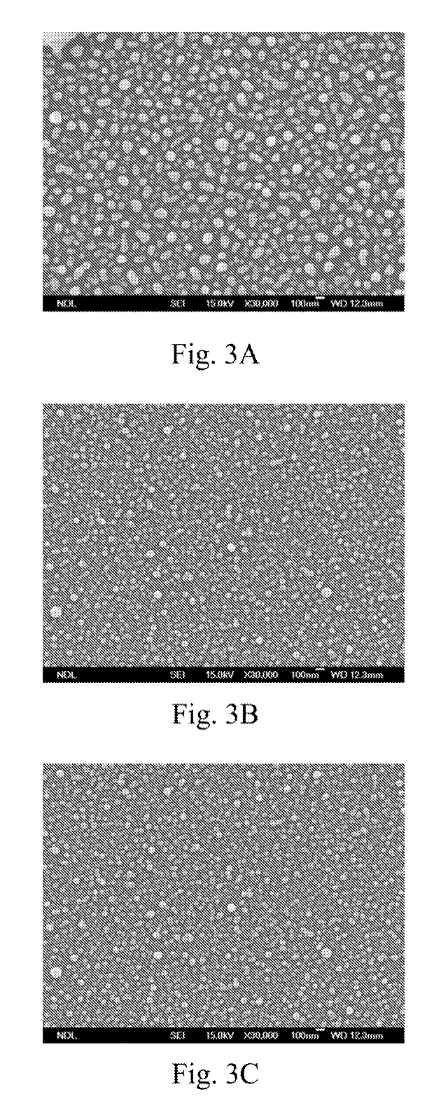

In this embodiment, the effect of metal deposition time on metal particles coverage was examined. The silicon substrate used was a <100> single crystal silicon substrate. The meal deposition status was observed by scanning electron microscope (SEM). FIGS. 2A-2C are SEM photographs of metal particles on silicon substrate of Examples 1-3, and FIGS. 3A-3C are SEM photographs of metal particles on silicon substrate of Examples 4-6, respectively. It can be clearly seen from Table 1, the metal articles coverage increase when the deposition time increases for both Au³⁺ and Ag⁺ ions.

TABLE 1
Effect of the metal deposition time on the metal particles coverage.

| | Electroless plating | Deposition | Metal particles |
|---|---|---|---|
| Example | solution | time (sec) | coverage (%) |
| 1 | 0.01M HAuCl₄ + | 15 | 7.6 |
| 2 | 2.4M HF | 30 | 12.6 |
| 3 | | 60 | 26.3 |
| 4 | 0.01M AgNO₃ + | 15 | 55 |
| 5 | 2.4M HF | 30 | 63 |
| 6 | | 60 | 80 |

### Embodiment 2

### Effect of Metal Particles Coverage on the Shapes Nano/Micro-Structures

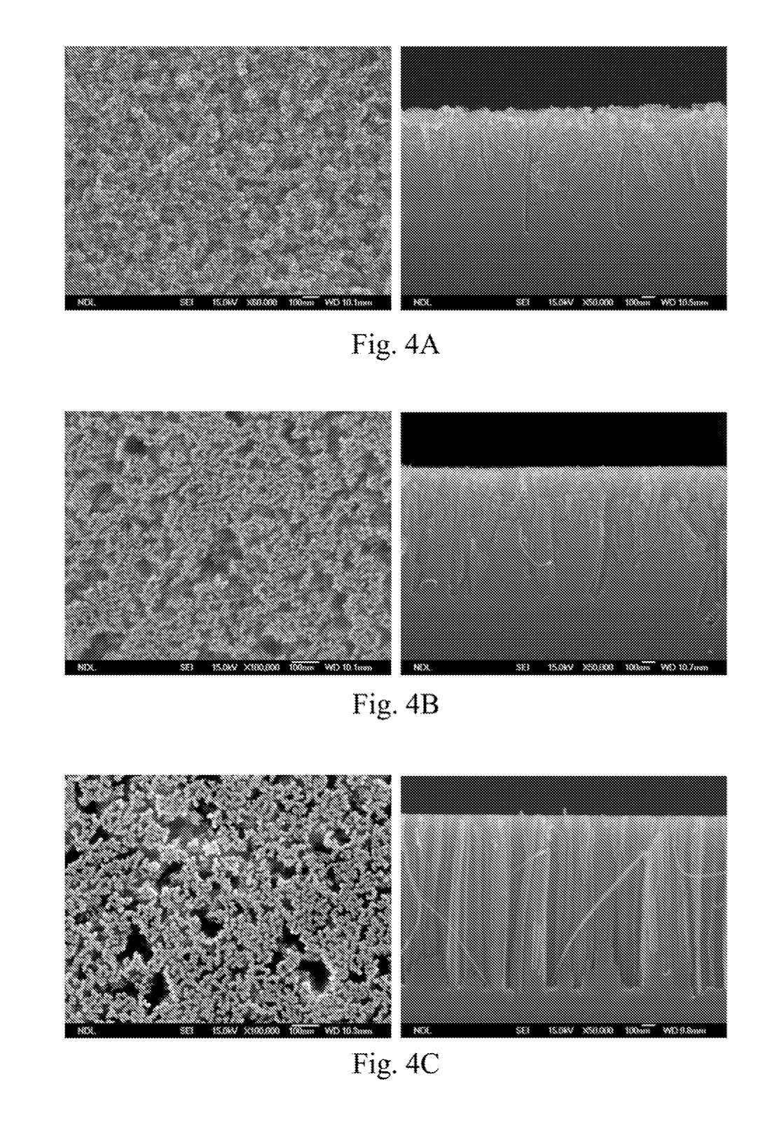

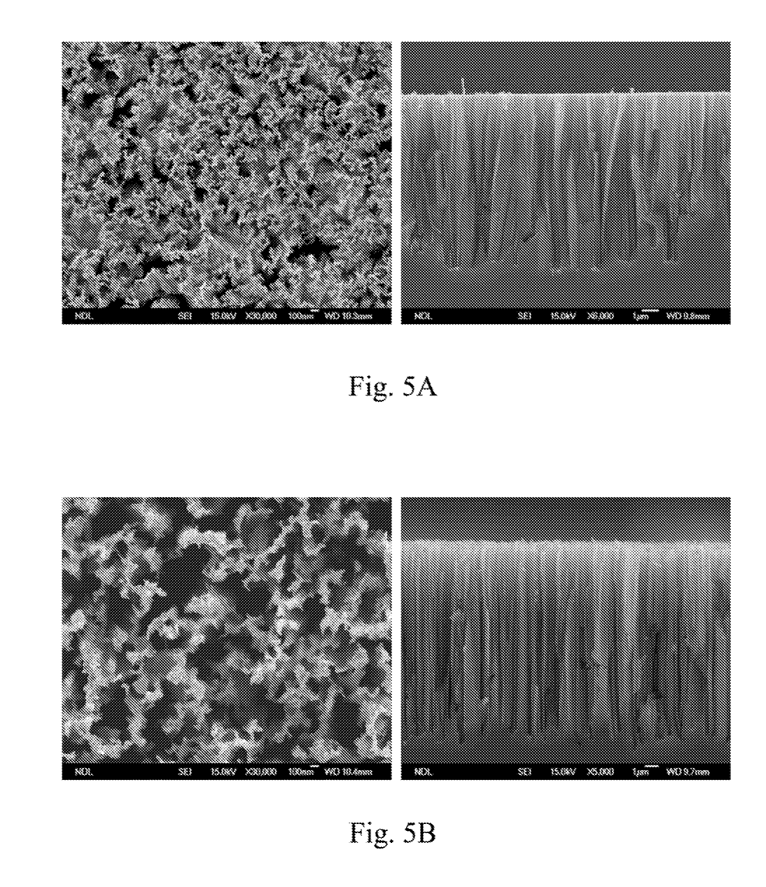

In this embodiment, effect of metal particles coverage on the shapes of nano/micro-structures was examined. The Examples 1-5 in Table 1 above were carried on to perform the metal-assist etching step 130 in FIG. 1. The shapes of the prepared nano/micro-structure were observed by SEM. FIGS. 4A-4C are SEM photographs showing various shapes of nano/micro-structure of Examples 1-3, and FIGS. 5A-5B are SEM photographs showing various shapes of nano/micro-structure of Examples 4-5, where the photographs on the left are top vies and photographs on the right are lateral view. From Table 2 and FIGS. 4A-5B, the etching depth was increased and the shape of the nano/micro-structures was changed from porous to wire when the metal particles coverage increases.

TABLE 2
Effect of metal particles coverage on the shapes of nano/micro-structures.

| | | | Metal-assist | | | |
|---|---|---|---|---|---|---|
| | | Metal | etching | | | |
| | Electroless | particles | solution | Etching | Etching | Shape of |
| | plating | coverage | (volume | time | depth | nano/micro |
| Example | solution | (%) | ratio) | (s) | (μm) | structure |
| 1 | 0.01M | 7.6 | ^{a}HF:^{b}H₂O₂:^{c}EtOH = | 60 | 0.6 | porous |
| 2 | HAuCl₄ + | 12.6 | 1:1:1 | 60 | 1.2 | filament |
| 3 | 2.4M HF | 26.3 | | 60 | 1.5 | wire |
| 4 | 0.01M | 55 | HF:H₂O₂ = | 60 | 10 | porous |
| 5 | AgNO₃ + | 63 | 1:1 | 60 | 14.1 | wire |
| | 2.4M HF | | | | | |

^{a}49 wt % HF;
^{b}31 wt % H₂O₂;
^{c}99.7 wt % EtOH.

### Embodiment 3

### Effect of Etching Time on Etching Depth

In this embodiment, the effect of etching time on etching depth was examined. In examples 3 and 7, the electroless plating solution is 0.01 M HAuCl₄ and 2.4 M HF, the deposition time is 60 seconds, and the metal particles coverage is 26.3%. In examples 5 and 8, the electroless plating solution is 0.01 M AgNO₃ and 2.4 M HF, the deposition time is 30 seconds, and the metal particles coverage is 63%. The silicon substrate used was a <100> single crystal silicon substrate in all examples of Table 3.

From Table 3, it can be seen that the etching depth increased when the etching time increased.

TABLE 3
Effect of etching time on etching depth.

| | Metal-assist etching | | | Shape of |
|---|---|---|---|---|
| | solution | Etching | Etching | nano/micro |
| Example | (volume ratio) | time (s) | depth (μm) | structure |
| 3 | ^{a}HF:^{b}H₂O₂:^{c}EtOH = | 60 | 1.5 | wire |
| 7 | 1:1:1 | 180 | 3.0 | wire |
| 5 | HF:H₂O₂ = | 60 | 14.1 | wire |
| 8 | 1:1 | 300 | 50 | wire |

^{a}49 wt % HF;
^{b}31 wt % H₂O₂;
^{c}99.7 wt % EtOH.

### Embodiment 4

### Effect of H₂O₂ Concentration on the Shape of Nano/Micro-Structure

In this embodiment, effect of H₂O₂ concentration on the shape of nano/micro-structure was examined. The examples in Table 4, the electroless plating solution is 0.01 M HAuCl₄ and 2.4 M HF, the deposition time is 30 seconds, and the metal particles coverage is 12.6% From Table 4, the shape of nano/micro structure was changed from filament to wire when the H₂O₂ concentration increased, since the ratio of the lateral etching rate over the vertical etching rate was increased by the increase of H₂O₂ concentration.

TABLE 4
Effect of H₂O₂ concentration on the shape of nano/micro-structure.

| | Metal-assist etching | | Etching | Shape of |
|---|---|---|---|---|
| | solution | Etching | depth | nano/micro |
| Example | (volume ratio) | time (s) | (μm) | structure |
| 2 | ^{a}HF:^{b}H₂O₂:^{c}EtOH = | 60 | 1.2 | filament |
| | 1:1:1 | | | |
| 9 | HF:H₂O₂:EtOH = | 60 | 1.8 | wire |
| | 1:2:1 | | | |

^{a}49 wt % HF;
^{b}31 wt % H₂O₂;
^{c}99.7 wt % EtOH.

### Embodiment 5

### Effect of HF Concentration on the Shape of Nano/Micro-Structure

In this embodiment, effect of H₂O₂ concentration on the shape of nano/micro-structure was examined. The examples in Table 4, the electroless plating solution is 0.01 M HAuCl₄ and 2.4 M HF, the deposition time is 30 seconds, and the metal particles coverage is 12.6% From Table 5, the shape of nano/micro structure was changed from filament to porous when the HF concentration increased, since the ratio of the lateral etching rate over the vertical etching rate was decreased by the increase of HF concentration.

TABLE 5
Effect of HF concentration on the shape of nano/micro-structure.

| | Metal-assist etching | | Etching | Shape of |
|---|---|---|---|---|
| | solution | Etching | depth | nano/micro |
| Example | (volume ratio) | time (s) | (μm) | structure |
| 2 | ^{a}HF:^{b}H₂O₂:^{c}EtOH = | 60 | 1.2 | filament |
| | 1:1:1 | | | |
| 10 | HF:H₂O₂:EtOH = | 60 | 0.7 | porous |
| | 2:1:1 | | | |

Accordingly, since only wet processes are used in the preparation method, and the preparation method can be performed under room temperature and atmospheric pressure. Therefore, no extra energy is needed to adjust the temperature, pressure, or voltage. The nano/micro-structures can be formed in a rapid, low energy consumption, and low cost way. Furthermore, the applications of the nano/micro-structures are quite popular. The nano/micro-structures can be a light-absorbing layer, an anti-reflection layer, or a substrate of mass spectrometer detection for increase detection sensitivity, for example.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A method of preparing nano/micro-structure, the method comprising:
immersing a silicon substrate in an electroless plating solution to deposit a plurality of metal particles on the silicon substrate, wherein the electroless plating solution comprises a metal ion and HF; and
immersing the silicon substrate in a metal-assist etching solution to etch the silicon substrate under the metal particles to form a plurality of nano/micro-structures, wherein the metal-assist etching solution comprises HF and H₂O₂.

2. The method of claim 1, wherein the metal-particles coverage on the silicon substrate is about 5-70%.

3. The method of claim 1, wherein the shape of the nano/micro-structure is porous, filament, or wire.

4. The method of claim 3, wherein the values of the metal-particles coverage arranged in order is porous nano/micro-structure>filament nano/micro-structure>wire nano/micro-structure when the composition of the metal-assist etching solution and the etching time is the same.

5. The method of claim 3, wherein the H₂O₂ concentration, in the metal-assist etching solution, arranged in order is porous nano/micro-structure<filament nano/micro-structure<wire nano/micro-structure when the composition of the electroless plating solution and the HF concentration in the metal-assist etching solution is the same.

6. The method of claim 3, wherein the HF concentration, in the metal-assist etching solution, arranged in order is porous nano/micro-structure>filament nano/micro-structure>wire nano/micro-structure when the composition of the electroless plating solution, the deposit time, and the H₂O₂ concentration in the metal-assist etching solution is the same.

7. The method of claim 1, wherein the metal ion is Au³⁺, Ag⁺, Pt⁴⁺ or Cu²⁺.

8. The method of claim 1, wherein the metal-assist etching solution further comprises a solvent.

9. The method of claim 1, wherein the silicon substrate comprises single crystal silicon.

10. A nano/micro-structure on a silicon substrate, the nano/micro-structure is prepared by the method of claim 1.
